(19) United States
(12) Patent Application Publication
(10) Pub. No.: US 2016/0099256 A1
(43) Pub. Date: Apr. 7, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Hiroki OKAMOTO, Nishinomiya (JP)

(73) Assignee: Kabushiki Kaisha Toshiba, Minato-ku (JP)

(21) Appl. No.: 14/635,226

(22) Filed: Mar. 2, 2015

Related U.S. Application Data
(60) Provisional application No. 62/060,310, filed on Oct. 6, 2014.

(51) Int. Cl. H01L 27/115

(52) U.S. Cl. CPC H01L 27/11582; H01L 27/1157

(57) ABSTRACT

According to one embodiment, a semiconductor memory device includes a substrate; a memory cell array including a plurality of memory cells and stacked on the substrate; a first transistor; an interlayer insulating layer covering the first transistor; and a first contact portion. The first transistor includes a first gate insulating film which is disposed on the substrate, a first gate electrode which is disposed on the first gate insulating film, and a first semiconductor layer which includes an upper surface at a higher position than an interface between the substrate and the first gate insulating film and a bottom surface at a deeper position than the interface between the substrate and the first gate insulating film. The first contact portion penetrates the interlayer insulating layer to reach the first semiconductor layer and connects the plurality of memory cells and the first transistor electrically.

This application is based upon and claims the benefit of priority from U.S. Provisional Patent Application 62/060,310 field on Oct. 6, 2014; the entire contents of which are incorporated herein by reference.

### FIELD

Embodiments described herein relate generally to a semiconductor memory device and a method for manufacturing same.

### BACKGROUND

A three-dimensionally structured memory device is proposed in which a memory cell array that includes a plurality of memory cells stacked with an insulating layer interposed therebetween is disposed.

A contact with a high aspect ratio is required to be formed in a control circuit that is formed in a substrate when the number of memory cells stacked is increased.

### BRIEF DESCRIPTION OF THE DRAWINGS

FIG. 1 is a schematic perspective view of a memory cell array of an embodiment;

FIG. 2 is a schematic cross-sectional view of the memory cell array and a peripheral circuit of the embodiment;

FIG. 3 is a schematic cross-sectional view of an enlarged part of the columnar portion of the embodiment;

FIG. 4A to FIG. 5 are schematic cross-sectional views showing a method for manufacturing the peripheral circuit of the embodiment;

FIG. 6 is a schematic cross-sectional view of a peripheral circuit of another embodiment;

FIG. 7A to FIG. 8 are schematic cross-sectional views showing a method for manufacturing the peripheral circuit of the another embodiment; and

FIG. 9 is a schematic perspective view of another example of the memory cell array of the embodiment.

### DETAILED DESCRIPTION

According to one embodiment, a semiconductor memory device includes a substrate; a memory cell array including a plurality of memory cells and stacked on the substrate; a first transistor; an interlayer insulating layer covering the first transistor; and a first contact portion. The first transistor includes a first gate insulating film which is disposed on the substrate, a first gate electrode which is disposed on the first gate insulating film, and a first semiconductor layer which includes an upper surface at a higher position than an interface between the substrate and the first gate insulating film and a bottom surface at a deeper position than the interface between the substrate and the first gate insulating film. The first contact portion penetrates the interlayer insulating layer to reach the first semiconductor layer and connects the plurality of memory cells and the first transistor electrically.

Hereinafter, an embodiment will be described with reference to the accompanying drawings. The same constituent in each drawing is given the same reference sign.

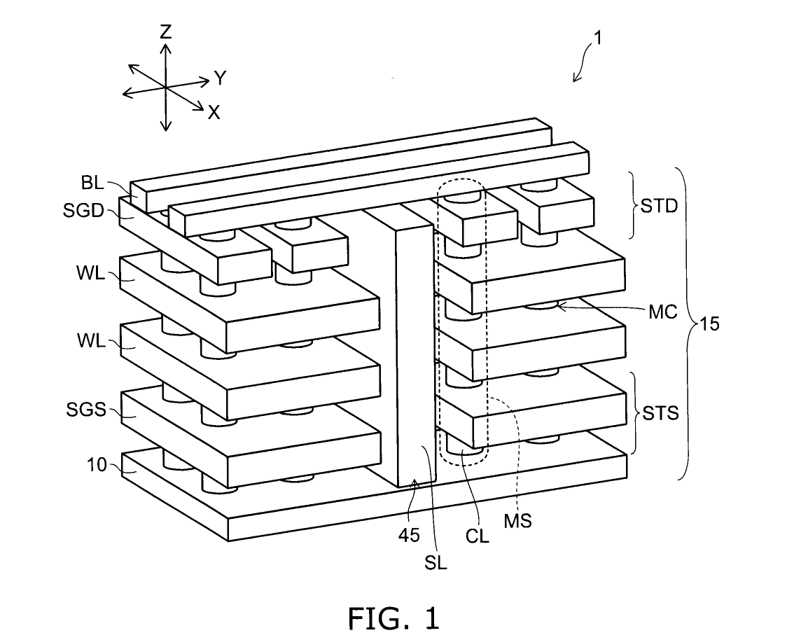

FIG. 1 is a schematic perspective view of a memory cell array of the embodiment. Illustrations of an insulating layer and the like are omitted for easy understanding in FIG. 1.

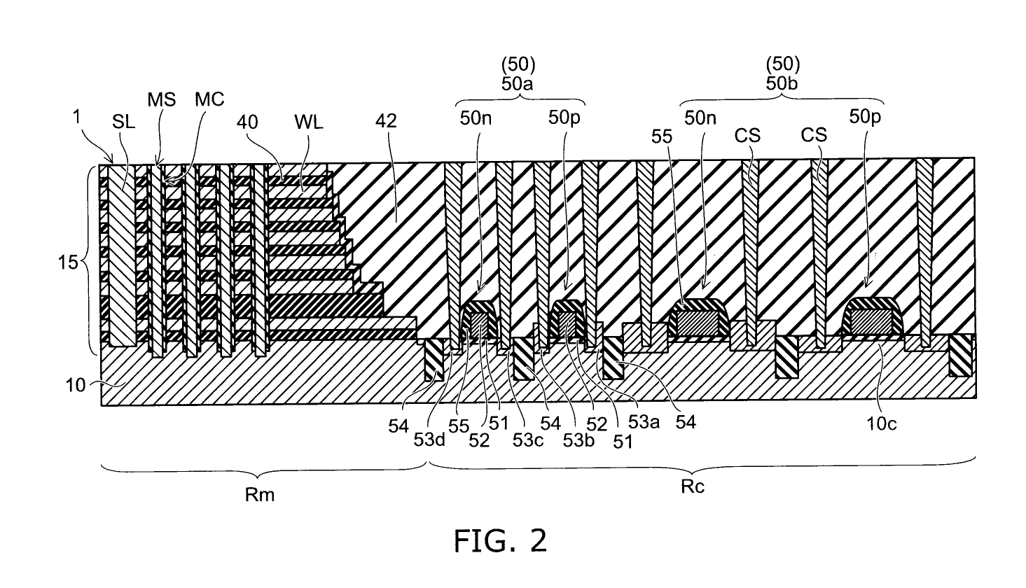

FIG. 2 is a schematic cross-sectional view of the memory cell array and a peripheral circuit (control circuit) of the embodiment. Upper-layer wiring and the like that electrically connect a memory region Rm and a peripheral circuit region Rc are omitted in FIG. 2.

In FIG. 1, two directions that are parallel to the major surface of a substrate 10 and are orthogonal to each other are set as an X-direction and a Y-direction, and a direction that is orthogonal to both of the X-direction and the Y-direction is set as a Z-direction (direction of stacking).

A memory cell array 1 includes a plurality of memory strings MS as illustrated in FIG. 1.

A source-side selector gate SGS is disposed on the substrate 10 with an insulating layer 40 interposed therebetween. An insulating layer is disposed on the source-side selector gate SGS, and a stacked body 15 in which a plurality of electrode layers WL and a plurality of insulating layers 40 are alternately stacked on each other one by one is disposed on the insulating layer. The number of electrode layers WL is illustrated as an example in the drawings and is arbitrary.

For example, the plurality of electrode layers WL is separately stacked each other. The plurality of insulating layers 40, for example, includes an air gap. The layer number of the plurality of electrode layers WL is no less than 16.

The insulating layer 40 is disposed on the uppermost electrode layer WL, and a drain-side selector gate SGD is disposed on the insulating layer. The stacked body 15 includes the source-side selector gate SGS, the plurality of electrode layers WL thereon, and the drain-side selector gate SGD.

The source-side selector gate SGS, the drain-side selector gate SGD, and the electrode layer WL are silicon layers that contain silicon as a main component. Boron, for example, is doped as an impurity in the silicon layer for providing conductivity. The source-side selector gate SGS, the drain-side selector gate SGD, and the electrode layer WL may include at least any one of metal and a metal silicide. The source-side selector gate SGS, the drain-side selector gate SGD, and the electrode layer WL may be made of metal. An insulating film, for example, that mainly contains silicon oxide is used in the insulating layer 40.

The thickness of the drain-side selector gate SGD and the source-side selector gate SGS is greater than the thickness of one electrode layer WL. The drain-side selector gate SGD and the source-side selector gate SGS, for example, may be disposed plurally. The thickness of the drain-side selector gate SGD and the source-side selector gate SGS may be smaller than or equal to the thickness of one electrode layer WL. Similarly, the drain-side selector gate SGD and the source-side selector gate SGS may be disposed plurally in this case. The “thickness” here indicates the thickness of the stacked body 15 in the direction of stacking (Z-direction).

A columnar portion CL is disposed in the stacked body 15 extending in the Z-direction. The columnar portion CL penetrates the stacked body 15. The columnar portion CL, for example, is formed as a cylinder or an elliptic cylinder. The columnar portion CL is electrically connected to the substrate 10.

A groove 45 is disposed in the stacked body 15 penetrating the stacked body 15. A source layer SL is disposed in the groove 45, and the side surface of the source layer SL is covered by an insulating film. Conductive material is used as the source layer SL.

The lower end of the source layer SL is electrically connected to a channel body 20 (semiconductor body) of the columnar portion CL through the substrate 10. The upper end of the source layer SL is electrically connected to a transistor 50 in the peripheral circuit region Rc through unillustrated wiring.

The source layer SL, for example, may be disposed between the substrate 10 and the stacked body 15. In this case, an unillustrated contact layer is disposed in the groove 45, and the source layer SL is electrically connected to the transistor 50 in the peripheral circuit region Rc through the contact layer.

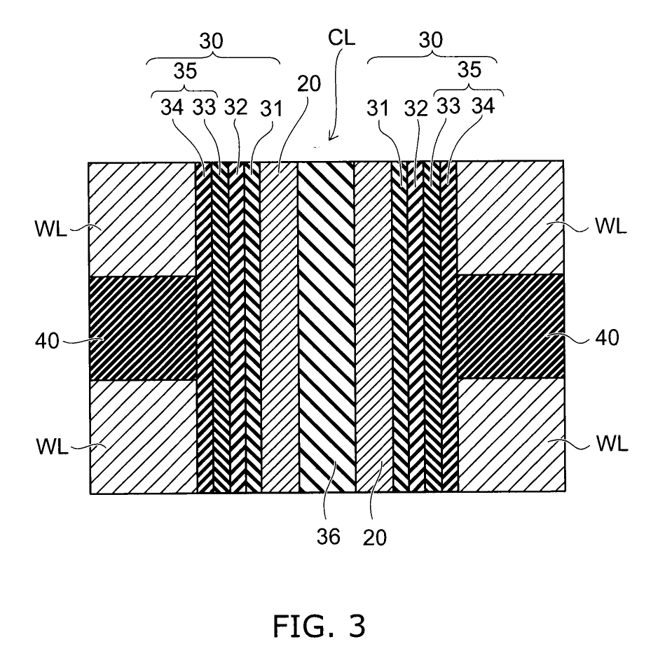

FIG. 3 is a schematic cross-sectional view of an enlarged part of the columnar portion CL of the embodiment.

The columnar portion CL is formed in a memory hole that is formed in the stacked body 15 which includes the plurality of electrode layers WL and the plurality of insulating layers 40. The channel body 20 is disposed in the memory hole as a semiconductor channel. The channel body 20, for example, is a silicon film that includes silicon as a main component.

The channel body 20 is disposed as a tube that extends in the direction of stacking in the stacked body 15. The upper end of the channel body 20 is connected to a bit line BL (wiring) illustrated in FIG. 1, and the lower end of the channel body 20 is connected to the substrate 10. Each bit line BL extends in the Y-direction.

A memory film 30 is disposed between the electrode layer WL and the channel body 20. The memory film 30 includes a block insulating film 35, a charge accumulation film 32, and a tunnel insulating film 31.

The block insulating film 35, the charge accumulation film 32, and the tunnel insulating film 31 are disposed between the electrode layer WL and the channel body 20 in this order from the electrode layer WL side. The block insulating film 35 is in contact with the electrode layer WL, and the tunnel insulating film 31 is in contact with the channel body 20. The charge accumulation film 32 is disposed between the block insulating film 35 and the tunnel insulating film 31.

The electrode layer WL surrounds the channel body 20 with the memory film 30 interposed therebetween. A core insulating film 36 is disposed inside the channel body 20.

The channel body 20 functions as a channel in a memory cell MC, and the electrode layer WL functions as a control gate of the memory cell MC. The charge accumulation film 32 functions as a data memory layer that accumulates charges implanted from the channel body 20. That is, the memory cell MC structured in a manner in which the control gate surrounds the channel is formed at the intersection part of the channel body 20 and each electrode layer WL.

A semiconductor memory device of the embodiment can freely delete or write data electrically and can hold the contents of the memory even when power is turned off.

The memory cell MC, for example, is a charge trap type. The charge accumulation film 32 plurally includes a trap site that captures charges and, for example, is a silicon nitride film.

The tunnel insulating film 31 serves as a potential barrier when charges are implanted to the charge accumulation film 32 from the channel body 20 or when charges accumulated in the charge accumulation film 32 are diffused into the channel body 20. The tunnel insulating film 31, for example, is a silicon oxide film.

Alternatively, a stacked film (ONO film) that is structured in a manner in which a silicon nitride film is interposed between a pair of silicon oxide films may be used as the tunnel insulating film 31. When the ONO film is used as the tunnel insulating film 31, a deletion operation is performed with a low electric field compared with a case of using a single silicon oxide film.

The block insulating film 35 prevents charges accumulated in the charge accumulation film 32 from being diffused into the electrode layer WL. The block insulating film 35 includes a cap film 34 that is disposed in contact with the electrode layer WL and a block film 33 that is disposed between the cap film 34 and the charge accumulation film 32.

The block film 33, for example, is a silicon oxide film. The cap film 34 has a higher dielectric constant than silicon oxide and, for example, is a silicon nitride film. Disposing such cap film 34 in contact with the electrode layer WL can suppress back tunneling of electrons that are implanted from the electrode layer WL during deletion. That is, using a stacked film of a silicon oxide film and a silicon nitride film as the block insulating film 35 can increase the ability to block charges.

A drain-side selector transistor STD is disposed in the upper end portion of the columnar portion CL, and a source-side selector transistor STS is disposed in the lower end portion of the columnar portion CL in the memory string MS as illustrated in FIG. 1.

The memory cell, the drain-side selector transistor STD, and the source-side selector transistor STS are vertical transistors in which currents flow in the direction of stacking (Z-direction) in the stacked body 15.

The drain-side selector gate SGD functions as the gate electrode (control gate) of the drain-side selector transistor STD. An insulating film is disposed between the drain-side selector gate SGD and the channel body 20 functioning as a gate insulating film of the drain-side selector transistor STD.

The source-side selector gate SGS functions as the gate electrode (control gate) of the source-side selector transistor STS. An insulating film is disposed between the source-side selector gate SGS and the channel body 20 functioning as a gate insulating film of the source-side selector transistor STS.

A plurality of memory cells MC is disposed between the drain-side selector transistor STD and the source-side selector transistor STS with each electrode layer WL as the control gate.

The plurality of memory cells MC, the drain-side selector transistor STD, and the source-side selector transistor STS are connected in series through the channel body 20 and constitute one memory string MS. The plurality of memory cells is disposed three-dimensionally in the X-direction, the Y-direction, and the Z-direction by arranging the memory string MS plurally in the X-direction and the Y-direction.

The substrate 10 includes the memory region Rm and the peripheral circuit region Rc as illustrated in FIG. 2. The memory string MS is disposed on the memory region Rm of the substrate 10. The transistor 50 is disposed on the peripheral circuit region Rc. The transistor 50, for example, includes a low breakdown voltage transistor 50a (first transistor) and a high breakdown voltage transistor 50b (second transistor). The transistor 50 is covered by an interlayer insulating layer 42. The interlayer insulating layer 42, for example, includes a silicon oxide film.

Each of the low breakdown voltage transistor 50a and the high breakdown voltage transistor 50b includes a p-type transistor 50p and an n-type transistor 50n. The p-type transistor 50p and the n-type transistor 50n include a gate insulating film 51, a gate electrode 52, a semiconductor layer 53 (53a, 53b, 53c, and 53d), a device isolation portion 54, and a first spacer 55 (first film).

The gate insulating film 51 is disposed on the substrate 10. The gate electrode 52 is disposed on the gate insulating film 51. The first spacer 55 is disposed on the upper surface of the gate insulating film 51 and around the gate electrode 52. A silicon nitride film, for example, is used as the first spacer 55. A stacked layer of a silicon oxide film and a silicon nitride film, for example, may also be used as the first spacer 55.

The semiconductor layer 53 is integrated with the substrate 10. Impurities (dopant atoms) are implanted into the semiconductor layer 53.

A pair of semiconductor layers 53 is favorably disposed in the transistor 50 provided that one of the pair is on the drain side, and the other is on the source side. The substrate 10 includes a channel region 10c that is disposed under the gate insulating film 51. The pair of semiconductor layers 53 is disposed in a manner in which the channel region 10c is interposed between the pair of semiconductor layers 53. The channel region 10c, for example, is a first conductivity type, and the pair of semiconductor layers 53 is a second conductivity type.

The thickness of the gate insulating film 51 of the high breakdown voltage transistor 50b is greater than the thickness of the gate insulating film 51 of the low breakdown voltage transistor 50a. The “thickness” here indicates the thickness of the stacked body 15 in the direction of stacking (Z-direction).

According to the embodiment, the semiconductor layer 53 is disposed protruding from the upper surface of the substrate 10. In FIG. 2, the semiconductor layers 53a and 53b are disposed in the p-type transistor 50p of the low breakdown voltage transistor 50a and the n-type transistor 50n of the high breakdown voltage transistor 50b protruding from the substrate 10. Conversely, the semiconductor layers 53c and 53d are disposed in the n-type transistor 50n of the low breakdown voltage transistor 50a and the p-type transistor 50p of the high breakdown voltage transistor 50b not protruding from the substrate 10.

The semiconductor layers 53a and 53b may be disposed in the n-type transistor 50n of the low breakdown voltage transistor 50a and the p-type transistor 50p of the high breakdown voltage transistor 50b protruding from the substrate 10.

The semiconductor layers 53a and 53b are adjacent to the gate electrode 52 with the first spacer 55 interposed therebetween. The position of the upper surface of the semiconductor layers 53a and 53b is higher than the position of the interface between the substrate 10 and the gate insulating film 51. The position of the bottom surface of the semiconductor layers 53a and 53b is deeper than the position of the interface between the substrate 10 and the gate insulating film 51. The semiconductor layer 53 includes the upper surface and the bottom surface. The upper surface of the semiconductor layer 53 is higher than a lower surface of the gate insulating film 51. The bottom surface of the semiconductor layer 53 is lower than the lower surface of the gate insulating film 51.

The semiconductor layer 53 is in contact with a contact portion CS. The contact portion CS penetrates the interlayer insulating layer 42 to reach the semiconductor layer 53. The contact portion CS is, for example, electrically connected to the memory cell array 1 through unillustrated upper-layer wiring, and the semiconductor layer 53 is electrically connected to the memory cell array 1 through the contact portion CS. The lower end portion (the bottom surface and a part of the side surface) of the contact portion CS is covered by the semiconductor layer 53.

According to the embodiment, the semiconductor layers 53a and 53b, as will be described below, are formed at a part of the substrate 10 that protrudes through epitaxial growth. Accordingly, the horizontal diffusion of impurities in the semiconductor layers 53a and 53b is controlled. For this reason, roll-offs caused by a short-channel effect can be ameliorated when the length of the gate of the transistor is shortened.

In addition, the semiconductor layers 53a and 53b are formed by implanting high-density impurities into a region from the protruding upper surface of the substrate 10 to a deep position. Accordingly, the area of the contact portion CS in contact with the semiconductor layers 53a and 53b can be increased. That is, the contact resistance between the transistor 50 and the contact portion CS can be reduced.

In addition to the above description, the depth of the diffusion of impurities in the direction of stacking in the substrate 10 can be controlled. Accordingly, the breakdown voltage of the transistor 50 can be increased.

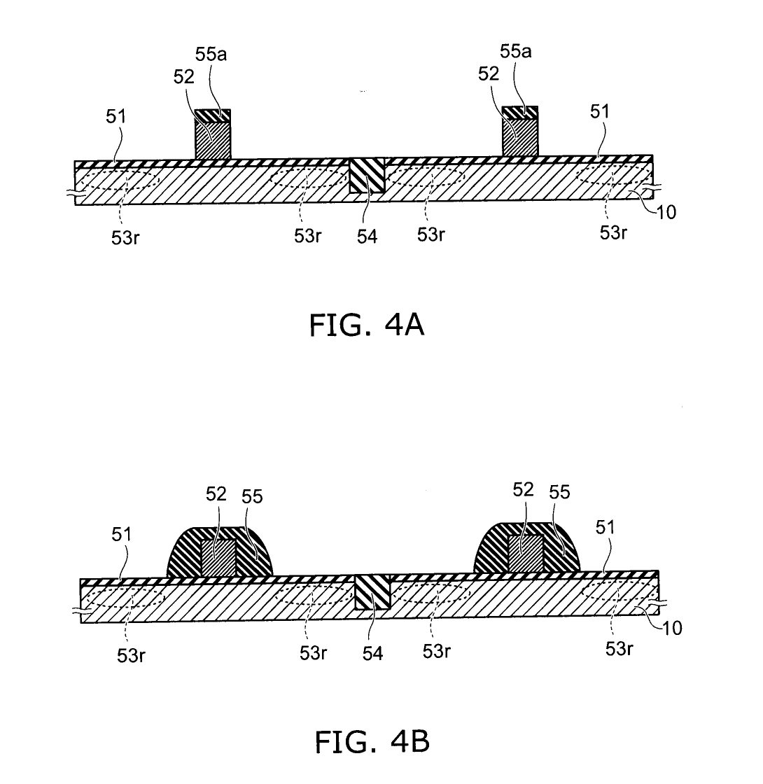

Next, a method for manufacturing the semiconductor memory device will be described with reference to FIG. 4A to FIG. 5.

The device isolation portion 54 that isolates a plurality of transistors is formed in the substrate 10 as illustrated in FIG. 4A.

The gate insulating film 51 (gate oxide film) is formed on the substrate 10. The gate electrode 52 is formed on the gate insulating film 51. An insulating film 55a is formed on the gate electrode 52. The gate electrode 52 is patterned through reactive ion etching (RIE) with the insulating film 55a as a mask. An activation target region 53r that becomes a source region or a drain region is formed between the gate electrode 52 and the device isolation portion 54. The gate oxide film may be completely etched to expose the substrate after the patterning through RIE in the process in FIG. 4A. In this case, although not illustrated, the gate oxide film is structured not to remain on a diffusion layer after the process.

The first spacer 55 (first film) is formed on the side surface of the gate electrode 52 as illustrated in FIG. 4B. Unnecessary parts of the first spacer 55 are removed through RIE after the first spacer 55 is formed on all the surfaces of the gate electrode 52 to cover the gate electrode 52. Accordingly, the first spacer 55 remains on the side wall of the gate electrode 52.

A silicon nitride film, for example, is used as the first spacer 55. A stacked film of a silicon oxide film and a silicon nitride film, for example, in which a silicon oxide film is used on the side surface of the gate electrode 52, and a silicon nitride film is used on the side surface of the silicon oxide film may also be used as the first spacer 55. Thereafter, the gate insulating film 51 that is formed on the substrate 10 is removed except for the gate insulating film 51 that is formed under the gate electrode 52 and under the first spacer 55.

The semiconductor layers 53a and 53b are formed in the activation target region 53r on the substrate 10 as illustrated in FIG. 5. The semiconductor layers 53a and 53b are used to form a protruding portion 10s of the substrate 10 through, for example, epitaxial growth with the substrate 10 as a nucleus. The height of the upper surface of the protruding portion 10s of the substrate 10 is greater than that of the position of the interface between the substrate 10 and the gate insulating film 51. The semiconductor layers 53a and 53b are formed in the protruding portion 10s of the substrate 10. The first spacer 55 regulates the horizontal growth of the protruding portion 10s of the substrate 10 toward the gate electrode 52 side.

The semiconductor layers 53a and 53b, for example, are formed by implanting impurities into the protruding portion 10s of the substrate 10. Impurities, for example, are implanted through ion implantation. Implanted impurities are activated through a thermal process to be diffused.

For example, Group 15 elements such as arsenic, phosphorus, and the like are used as impurities when forming the n-type transistor 50n. For example, Group 13 elements such as boron and the like are used as impurities when forming the p-type transistor 50p.

The position of the upper surface of the semiconductor layers 53a and 53b formed is higher than the position of the interface between the substrate 10 and the gate insulating film 51. The position of the bottom surface of the semiconductor layers 53a and 53b is deeper than the position of the interface between the substrate 10 and the gate insulating film 51. The upper surface of the semiconductor layer 53 is higher than a lower surface of the gate insulating film 51. The bottom surface of the semiconductor layer 53 is lower than the lower surface of the gate insulating film 51.

Next, the memory cell array 1 is formed in the memory region Rm as illustrated in FIG. 2. The interlayer insulating layer 42 is formed on the memory region Rm and the peripheral circuit region Rc.

A hole that penetrates the interlayer insulating layer 42 to reach the semiconductor layers 53a and 53b is formed through, for example, RIE that uses an unillustrated mask after the interlayer insulating layer 42 is formed.

Next, the contact portion CS is formed by filling the hole with a conductive film. The position of the bottom surface of the contact portion CS is deeper than the position of the interface between the substrate 10 and the gate insulating film 51.

Thereafter, the semiconductor memory device of the embodiment is formed by forming wiring and the like that are electrically connected to the memory cell array 1.

According to the embodiment, the semiconductor layers 53a and 53b are formed in the protruding portion 10s of the substrate 10 that is formed by using epitaxial growth. Accordingly, the diffusion of the semiconductor layers 53a and 53b including impurities in the direction of the channel can be controlled in a heating process when forming the memory cell array 1. For this reason, roll-offs caused by a short-channel effect in the transistor can be ameliorated. Furthermore, parasitic resistance can be reduced.

The semiconductor layers 53a and 53b are formed by implanting high-density impurities into the region from the upper surface of the protruding portion 10s of the substrate 10 to a deep position. Accordingly, an increase in the diameter of the hole and an increase in junction leakage due to dislocation of the hole in the depth direction can be suppressed when forming the contact portion CS.

The interlayer insulating layer 42 in the peripheral circuit region Rc is thickened along with an increase in the number of memory cells stacked when, for example, forming a three-dimensionally structured memory device. For this reason, the aspect ratio of the hole when forming the hole that penetrates the interlayer insulating layer 42 is increased, and the accuracy of the position in the depth direction (the position where etching is stopped) is degraded. Accordingly, the hole penetrates the diffusion layer that becomes the source region or the drain region to reach the p-n junction. This may cause an increase in junction leakage or the like.

Regarding this, the semiconductor layers 53a and 53b are formed in a region that includes the protruding portion 10s of the substrate 10 according to the embodiment. For this reason, the semiconductor layer 53 is formed to be thicker than that in the conventional technology. Accordingly, the bottom surface of the hole is easily formed in the high-density region in the semiconductor layers 53a and 53b. This suppresses an increase in junction leakage or the like.

Particularly, this is more effective on the p-type transistor 50p that uses Group 13 elements such as boron and the like as impurities than the n-type transistor 50n.

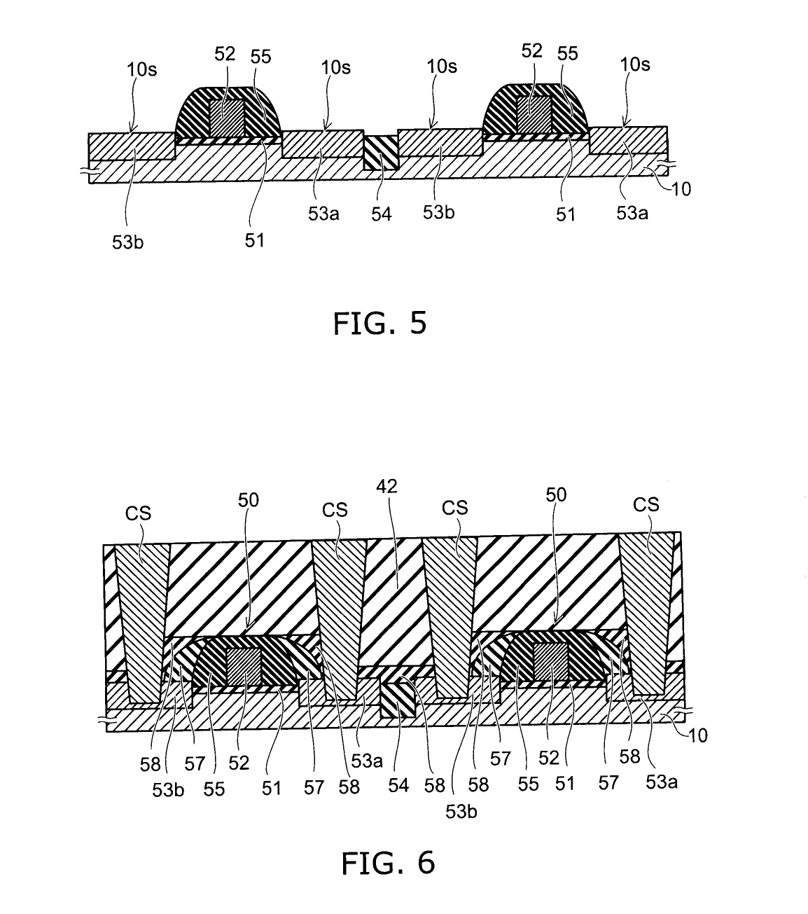

FIG. 6 is a schematic cross-sectional view of a transistor of another embodiment. The memory region Rm is the same as the memory region Rm described above and thus will not be described.

According to the embodiment, the transistor 50 further includes a second spacer 57 (second film) and an intermediate film in addition to the constituents in the above-described embodiment.

The second spacer 57 is disposed on the upper surface of the semiconductor layers 53a and 53b and on the side surface of the first spacer 55. The second spacer 57 covers the side surface of the first spacer 55. The second spacer 57 is disposed between the contact portion CS and the first spacer 55. Material such as a silicon oxide film that is different from that of the first spacer 55 is used as the second spacer 57.

The intermediate film 58 is disposed on the upper surface of the semiconductor layers 53a and 53b and on the side surface of the second spacer 57. The intermediate film 58 covers the side surface of the second spacer 57. Material such as a silicon nitride film that is different from that of the second spacer 57, the semiconductor layers 53a and 53b, and the interlayer insulating layer 42 is used as the intermediate film 58.

The intermediate film 58 is used as an etching stopper film when forming the contact portion CS. The contact portion CS penetrates the intermediate film 58. The intermediate film 58 is covered by the interlayer insulating layer 42.

Accordingly, an increase in junction leakage and the contact resistance due to dislocation of the contact portion CS in the width direction can be suppressed when forming the contact portion CS as will be described below.

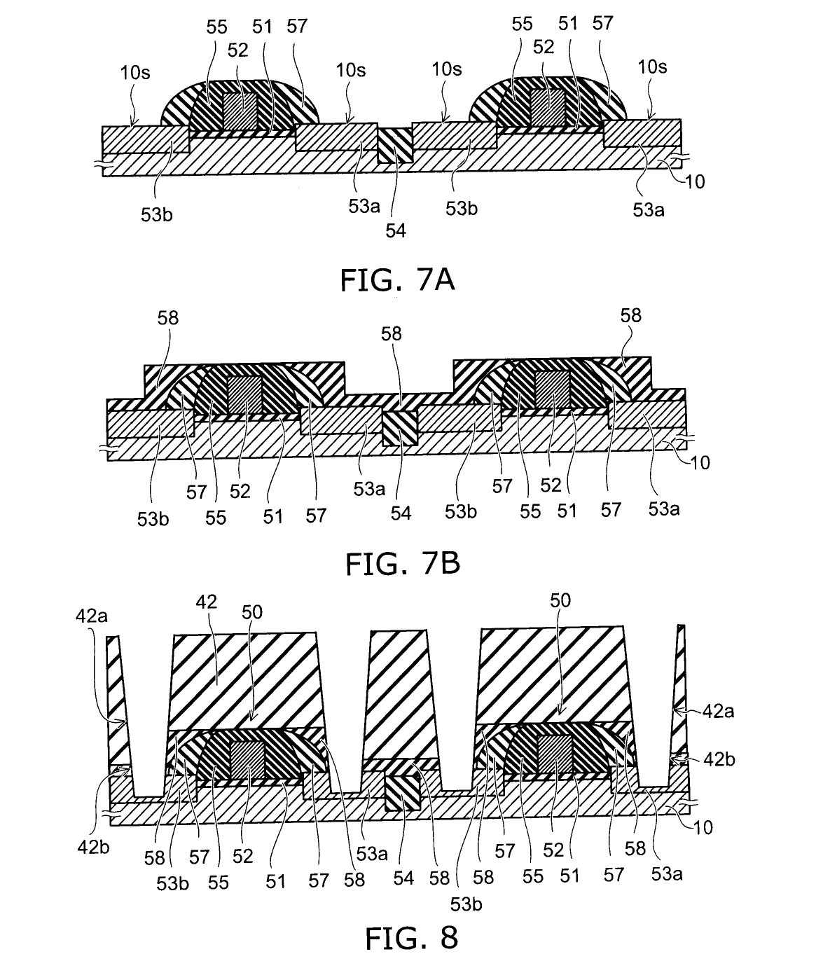

Next, a method for manufacturing the semiconductor memory device of another embodiment will be described with reference to FIG. 7A and FIG. 7B.

The device isolation portion 54 that isolates a plurality of transistors is formed in the substrate 10 as in the case of the above-described embodiment illustrated in FIG. 4A to FIG. 5.

The gate insulating film 51 is formed on the substrate 10. The gate electrode 52 is formed on the gate insulating film 51. The insulating film 55a is formed on the gate electrode 52. The gate electrode 52 is patterned through RIE with the insulating film 55a as a mask. The activation target region 53r that becomes a source region or a drain region is formed between the gate electrode 52 and the device isolation portion 54.

The first spacer 55 (first film) is formed on the side wall of the gate electrode 52. Unnecessary parts of the first spacer 55 are removed through RIE after the first spacer 55 is formed on all the surfaces of the gate electrode 52 to cover the gate electrode 52. Accordingly, the first spacer 55 remains on the side wall of the gate electrode 52.

Thereafter, the gate insulating film 51 that is formed on the substrate 10 is removed except for the gate insulating film 51 that is formed under the gate electrode 52 and under the first spacer 55.

The semiconductor layers 53a and 53b are formed in the activation target region 53r on the substrate 10. The semiconductor layers 53a and 53b are used to form the protruding portion 10s of the substrate 10 through, for example, epitaxial growth with the substrate 10 in a region that is adjacent to the first spacer 55 as a nucleus. The height of the upper surface of the protruding portion 10s of the substrate 10 is greater than that of the position of the interface between the substrate 10 and the gate insulating film 51. The semiconductor layers 53a and 53b are formed in the protruding portion 10s of the substrate 10.

The semiconductor layers 53a and 53b, for example, are formed by implanting impurities into the protruding portion 10s of the substrate 10. The position of the upper surface of the semiconductor layers 53a and 53b is higher than the position of the interface between the substrate 10 and the gate insulating film 51. The position of the bottom surface of the semiconductor layers 53a and 53b is deeper than the position of the interface between the substrate 10 and the gate insulating film 51. The upper surface of the semiconductor layer 53 is higher than a lower surface of the gate insulating film 51. The bottom surface of the semiconductor layer 53 is lower than the lower surface of the gate insulating film 51.

Next, the second spacer 57 (second film) is formed on the upper surface of the semiconductor layers 53a and 53b and on the side surface of the first spacer 55 as illustrated in FIG. 7A. Material such as a silicon oxide film that is different from that of the side surface of the first spacer 55 is used as the second spacer 57. Thereafter, the superfluous second spacer 57 that is formed on the upper surface of the semiconductor layers 53a and 53b is removed through, for example, etching.

The intermediate film 58 is formed on the upper surface of the semiconductor layers 53a and 53b and on the side surface of the second spacer 57 as illustrated in FIG. 7B. Material such as a silicon nitride film that is different from that of the second spacer is used as the intermediate film 58. The intermediate film 58 is used as an etching stopper film when forming the contact portion CS as will be described below.

Next, the memory cell array 1 is formed on the memory region Rm. The interlayer insulating layer 42 is formed on the memory region Rm and the peripheral circuit region Rc.

As illustrated in FIG. 8, a first hole 42a that penetrates the interlayer insulating layer 42 to reach the intermediate film 58 is formed through, for example, RIE that uses an unillustrated mask after the interlayer insulating layer 42 is formed. After forming the first hole 42a, a second hole 42b that penetrates the intermediate film 58 to reach the semiconductor layers 53a and 53b is formed through RIE by switching etching gas that is different from that in forming the first hole 42a.

Next, the first hole 42a and the second hole 42b are filled with conductive material (for example, metal such as tungsten and the like). Accordingly, the contact portion CS is formed as illustrated in FIG. 2. The position of the bottom surface of the contact portion CS is deeper than the position of the interface between the substrate 10 and the gate insulating film 51.

Thereafter, the semiconductor memory device of the embodiment is formed by forming wiring and the like that are electrically connected to the memory cell array 1.

According to the embodiment, roll-offs caused by a short-channel effect in the transistor can be ameliorated as in the case of the above-described embodiment. Furthermore, parasitic resistance can be reduced, and an increase in the diameter of the hole and an increase in junction leakage due to dislocation of the hole in the depth direction can be suppressed when forming the contact portion CS.

In addition to the above description, the second spacer 57 is formed according to the embodiment. Accordingly, an increase in junction leakage due to dislocation of the contact portion CS in the width direction can be suppressed when forming the contact portion CS.

The interlayer insulating layer 42 in the peripheral circuit region Rc is thickened along with an increase in the number of memory cells stacked when, for example, forming a three-dimensionally structured memory device. For this reason, a hole is easily dislocated in the width direction when forming the hole that penetrates the interlayer insulating layer 42. Accordingly, it is difficult to form the bottom surface of the hole in the high-density region in the semiconductor layer. This may cause an increase in junction leakage or the like.

Regarding this, the second spacer 57 is formed between the first spacer 55 and the intermediate film 58 according to the embodiment. For this reason, the second spacer 57 is used as an etching stopper when the second hole 42b is dislocated in the width direction while being formed by etching the intermediate film 58. Accordingly, the bottom surface of the hole is easily formed in the high-density region in the semiconductor layers 53a and 53b. This can control an an increase in junction leakage or the like.

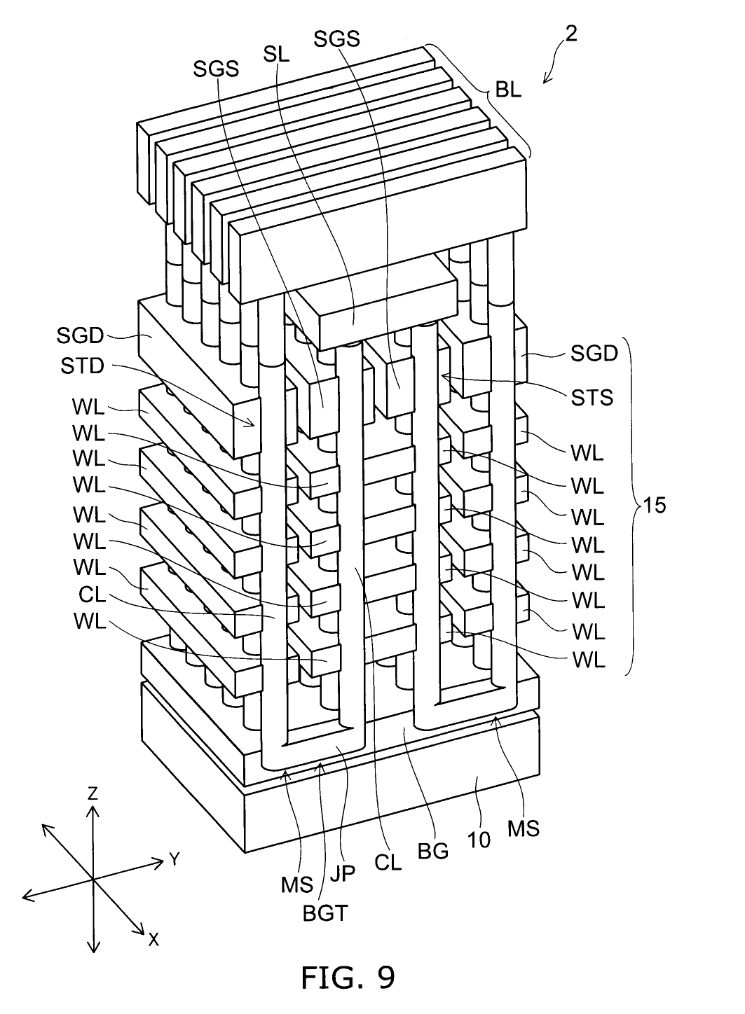

FIG. 9 is a schematic perspective view of another example of the memory cell array in the semiconductor memory device of the embodiment.

In FIG. 9, illustrations of an insulating layer and the like are omitted for easy understanding as in FIG. 1.

A back gate BG is disposed on the substrate 10 with an insulating layer interposed therebetween. The stacked body 15 in which the plurality of electrode layers WL and the plurality of insulating layers 40 are alternately stacked on each other is disposed on the back gate BG.

One memory string MS is formed as a U shape and includes a pair of columnar portions CL that extends in the Z-direction and a junction portion JP that joins each of the lower ends of the pair of columnar portions CL. The columnar portion CL, for example, is formed as a cylinder or an elliptic cylinder and penetrates the stacked body 15 to reach the back gate BG.

The drain-side selector gate SGD is disposed in one upper end portion of the pair of columnar portions CL, and the source-side selector gate SGS is disposed in the other upper end portion in the U-shaped memory string MS. The drain-side selector gate SGD and the source-side selector gate SGS are disposed on the uppermost electrode layer WL with the insulating layer 40 interposed therebetween. The stacked body 15 includes the source-side selector gate SGS, the drain-side selector gate SGD, and the plurality of electrode layers WL.

The drain-side selector gate SGD and the source-side selector gate SGS are separated by a slit in the Y-direction. The stacked body 15 that includes the drain-side selector gate SGD and the stacked body 15 that includes the source-side selector gate SGS are separated by a slit in the Y-direction. That is, the stacked body 15 of the memory string MS between the pair of columnar portions CL is separated by a slit in the Y-direction.

The source layer SL is disposed on the source-side selector gate SGS with an insulating layer interposed therebetween. A plurality of bit lines BL is disposed on the drain-side selector gate SGD and on the source layer SL with an insulating layer interposed therebetween. Each bit line BL extends in the Y-direction.

As in the case of the above-described embodiment, the semiconductor layers 53a and 53b and the second spacer 57 are disposed when a memory cell array 2 is used. Accordingly, roll-offs caused by a short-channel effect can be ameliorated when the length of the gate of the transistor is shortened. In addition, resistance between the transistor and the contact portion CS can be reduced.

In addition to the above description, the bottom surface of the contact portion is easily formed in the high-density region in the semiconductor layers 53a and 53b. This can suppress an increase in junction leakage, an increase in junction leakage and the contact resistance, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a memory cell array including a plurality of memory cells stacked on the substrate;
a first transistor provided on the substrate and including
a first gate insulating film;
a first gate electrode provided on the first gate insulating film; and
a first semiconductor layer provided on the substrate and including an upper surface being higher than a lower surface of the first gate insulating film and a bottom surface being lower than the lower surface of the first gate insulating film;
an interlayer insulating layer covering the first transistor; and
a first contact portion provided in the interlayer insulating layer and in the first semiconductor layer and electrically connected with the first transistor.

2. The device according to claim 1, wherein
a bottom surface of the first contact portion is lower than the lower surface of the first gate insulating film.

3. The device according to claim 1, wherein
the first transistor includes a first film provided between the first gate electrode and the first semiconductor layer.

4. The device according to claim 1, wherein
the first transistor includes an intermediate film provided between the first semiconductor layer and the interlayer insulating layer, the intermediate film including a material being different from a material of the first semiconductor layer and a material of the interlayer insulating layer, and
the first contact portion is provided in the intermediate film.

5. The device according to claim 3, wherein
the first transistor includes an intermediate film provided between the first semiconductor layer and the interlayer insulating layer, the intermediate film including a material being different from a material of the first semiconductor layer and a material of the interlayer insulating layer, and
the first contact portion is provided in the intermediate film.

6. The device according to claim 5, wherein
the first transistor includes a second film provided between the intermediate film and the first film and including a material being different from a material of the intermediate film and a material of the first film.

7. The device according to claim 6, wherein
the first film and the intermediate film include a silicon nitride film, and the second film and the interlayer insulating layer include a silicon oxide film.

8. The device according to claim 6, wherein
the second film covers a side wall of the first film.

9. The device according to claim 6, wherein
the intermediate film covers a side wall of the second film.

10. The device according to claim 6, wherein
the second film is provided between the first contact portion and the first film.

11. The device according to claim 1, further comprising:
a second transistor provided on the substrate and covered with the interlayer insulating layer and includes
a second gate insulating film being thicker than the first gate insulating film of the first transistor;
a second gate electrode provided on the second gate insulating film; and
a second semiconductor layer provided on the substrate and including an upper surface being higher than a lower surface of the second gate insulating film and a bottom surface being lower than the lower surface of the second gate insulating film; and
a second contact portion provided in the interlayer insulating layer and in the second semiconductor layer and electrically connected with the second transistor.

12. The device according to claim 1, wherein
a bottom surface of the first contact portion provided in the first semiconductor layer.

13. The device according to claim 1, wherein
the memory cell array includes
a stacked body including a plurality of electrode layers separately stacked each other,
a semiconductor body provided in the stacked body and extending in a direction of stacking in the stacked body, and
a charge accumulation film provided between the semiconductor body and the plurality of electrode layers.

14. A method for manufacturing a semiconductor memory device comprising:
forming a gate insulating film on a substrate and forming a gate electrode on the gate insulating film;
forming a protruding portion of the substrate from an upper surface of the substrate to a higher position than the position of an interface between the substrate and the gate insulating film through epitaxial growth;
forming a semiconductor layer by implanting impurities from the protruding portion to a deeper position than the position of the interface between the substrate and the gate insulating film;
forming an interlayer insulating layer that covers the gate electrode and the semiconductor layer; and
forming a contact portion that penetrates the interlayer insulating layer to reach the semiconductor layer up to a deeper position than the position of the interface between the substrate and the gate insulating film.

15. The method according to claim 14, further comprising:
forming a first film on a side wall of the gate electrode before forming the semiconductor layer.

16. The method according to claim 15, further comprising:
forming a second film that includes material which is different from the material of the first film on an upper surface of the semiconductor layer and on a side wall of the first film.

17. The method according to claim 16, further comprising:
forming an intermediate film that includes material which is different from the material of the interlayer insulating layer and the second film on the upper surface of the semiconductor layer and on a side wall of the second film.

18. The method according to claim 17, wherein
the forming of the contact portion includes
forming a first hole that reaches the intermediate film by etching the interlayer insulating layer,
forming a second hole that reaches the semiconductor layer by etching the intermediate film under the first hole, and
forming a conductive film in the first hole and the second hole.

19. The method according to claim 14, further comprising:
forming an intermediate film on the semiconductor layer and on a side wall of the first gate electrode.

20. The method according to claim 14, further comprising:
forming a memory cell array that includes a plurality of memory cells which is stacked on the substrate.
